(19) United States
(12) Patent Application Publication
(10) Pub. No.: US 2015/0211147 A1
(43) Pub. Date: Jul. 30, 2015

(54) CRUCIBLE, CRYSTAL GROWING APPARATUS, AND CRYSTAL GROWING METHOD

(71) Applicant: KYOCERA Corporation, Kyoto-shi, Kyoto (JP)

(72) Inventors: Katsuaki Masaki, Kyoto-shi (JP); Yutaka Kuba, Kyoto-shi (JP); Chiaki Domoto, Kyoto-shi (JP)

(21) Appl. No.: 14/417,529

(22) PCT Filed: Jul. 26, 2013
(86) PCT No.: PCT/JP2013/070369

§ 371 Date: Jan. 26, 2015

(30) Foreign Application Priority Data
Jul. 27, 2012 (JP) 2012-166634

(51) Int. Cl. C30B 15/10; C30B 29/36

(52) U.S. Cl. CPC C30B 15/10; C30B 29/36

(57) ABSTRACT

A crucible 1 according to an embodiment of the present invention is a crucible 1 which is used in a solution growth method for growing a crystal of silicon carbide on a lower surface 3B of a seed crystal 3 from a solution 2, by accommodating the solution 2 of silicon containing carbon in the crucible 1, by allowing the lower surface 3B of the seed crystal 3 to contact with the solution 2 from above, and by pulling the seed crystal 3 upward. The crucible is made of carbon and includes a solution adjustment member 4 which is fixed to an inner wall surface 1A so as to be positioned between a bottom surface 1B and a liquid surface of the solution 2 when the crucible 1 is used and which includes a through hole 4a overlapped with an inner side of the seed crystal 3 disposed above.

### TECHNICAL FIELD

The present invention relates to a crucible including a solution adjustment member, a crystal growing apparatus using the crucible, and a crystal growing method for growing crystals using the crucible.

### BACKGROUND ART

Currently, as crystals which are receiving attention these days, there is silicon carbide (SiC) which is a compound of carbon and silicon. Silicon carbide is receiving attention because of various advantages such as a wider bandgap than that of silicon, high electric field strength (good voltage endurance) against dielectric breakdown, high heat conduction, high heat resistance, good chemical resistance, and good radiation resistance, and is receiving attention in a wide range of fields such as heavy electric machinery including nuclear energy, transportation including vehicle and aircraft, and home electric appliances. The crystal of silicon carbide can be grown on a surface of a seed crystal, for example, by a solution growth method or a sublimation method. A method for growing the crystal of silicon carbide by the solution growth method is described, for example, in Japanese Unexamined Patent Application Publication No. 2000-264790.

### SUMMARY OF INVENTION

In studying and developing of growing a crystal which is made of silicon carbide by a solution growth method, one of the issues is how to increase the growing speed of the crystal when the crystal to be grown on a lower surface of a seed crystal is desired to be large in size or long in length. The present invention is devised in consideration of such a situation, and aims to provide a crucible which can increase the growing speed of the crystal, a crystal growing apparatus which uses the crucible, and a crystal growing method.

A crucible according to an embodiment of the present invention is a crucible made of carbon and used in a solution growth method for growing a crystal of silicon carbide on a lower surface of a seed crystal from a solution by accommodating the solution of silicon containing carbon in the crucible, by allowing a lower surface of the seed crystal to contact with the solution from above, and by pulling the seed crystal upward. The crucible includes a solution adjustment member that includes a through hole overlapped with an inner side of the seed crystal disposed above and that is fixed to an inner wall surface of the crucible so as to be positioned between a bottom surface of the crucible and a liquid surface of the solution when the crucible is used.

A crystal growing apparatus according to an embodiment of the present invention includes the above-described crucible and a holding member that holds a seed crystal and is capable of inserting and pulling up the seed crystal from an opening portion of the crucible.

A crystal growing method according to an embodiment of the present invention includes: preparing the above-described crucible, a holding member which holds a seed crystal and is capable of inserting and pulling up the seed crystal from an opening portion of the crucible, and the seed crystal which is made of silicon carbide and whose upper surface is held by the holding member; accommodating in the crucible a solution of silicon including carbon so that the liquid surface is positioned above the solution adjustment member; allowing a lower surface of the seed crystal to contact with the solution by inserting the seed crystal from the opening portion of the crucible by the holding member; and growing the crystal of silicon carbide on a lower surface of the seed crystal by pulling up the seed crystal by the holding member in a state where the lower surface of the seed crystal is disposed to be overlapped with the through hole of the solution adjustment member.

According to the present invention, the following effects can be obtained. That is, when the crystal of silicon carbide is grown by the solution growth method, convection with respect to the solution containing a large amount of carbon is likely to strike the lower surface of the seed crystal in the crucible and the growing speed of the crystal that is grown on the lower surface of the seed crystal can be increased.

### BRIEF DESCRIPTION OF DRAWINGS

FIG. 1 is a diagram illustrating an example of a crystal growing apparatus according to an embodiment of the present invention in which a crucible according to an embodiment of the present invention is installed, and corresponds to a cross-sectional view which is cut in a vertical direction.

FIG. 2 is an enlarged cross-sectional view in which the crucible illustrated in FIG. 1 and a holding member are enlarged, and corresponds to a cross section which is cut along line A-A′ in FIG. 3.

FIG. 3 is a plan view of the crucible illustrated in FIGS. 1 and 2 in perspective plan view.

FIG. 4 is a schematic cross-sectional view illustrating convection generated when a crystal is grown on a lower surface of a seed crystal by a solution growth method in the crucible illustrated in FIG. 1.

FIG. 5 is a diagram illustrating a modification example of the crucible according to the embodiment of the present invention, and corresponds to a cross section which is cut along the line A-A′ in FIG. 3.

FIG. 6 is a diagram illustrating a modification example of the crucible according to the embodiment of the present invention, and corresponds to the cross section which is cut along the line A-A′ in FIG. 3.

FIG. 7 is a diagram illustrating a modification example of the crucible according to the embodiment of the present invention, and corresponds to the cross section which is cut along the line A-A′ in FIG. 3.

FIG. 8 is a diagram illustrating a modification example of the crucible according to the embodiment of the present invention, and is a plan view when the crucible is viewed in a perspective plan view.

FIG. 9 is a diagram illustrating a modification example of the crucible according to the embodiment of the present invention, and corresponds to the cross section which is cut along the line A-A′ in FIG. 3.

FIG. 10 is a diagram illustrating a modification example of the crucible according to the embodiment of the present invention, and corresponds to the cross section which is cut along the line A-A′ in FIG. 3.

FIG. 11 is a diagram illustrating a modification example of the crucible according to the embodiment of the present invention, and corresponds to the cross section which is cut along the line A-A′ in FIG. 3.

FIG. 12 is a cross-sectional view illustrating a process of a crystal growing method according to an embodiment of the present invention, and corresponds to the cross section which is cut along the line A-A′ in FIG. 3.

FIG. 13 is a cross-sectional view illustrating a process of the crystal growing method according to the embodiment of the present invention, and corresponds to the cross section which is cut along the line A-A′ in FIG. 3.

FIG. 14 is a cross-sectional view illustrating a process of the crystal growing method according to the embodiment of the present invention, and corresponds to the cross section which is cut along the line A-A′ in FIG. 3.

FIG. 15 is a cross-sectional view illustrating a process of the crystal growing method according to the embodiment of the present invention, and corresponds to the cross section which is cut along the line A-A′ in FIG. 3.

### DESCRIPTION OF EMBODIMENTS

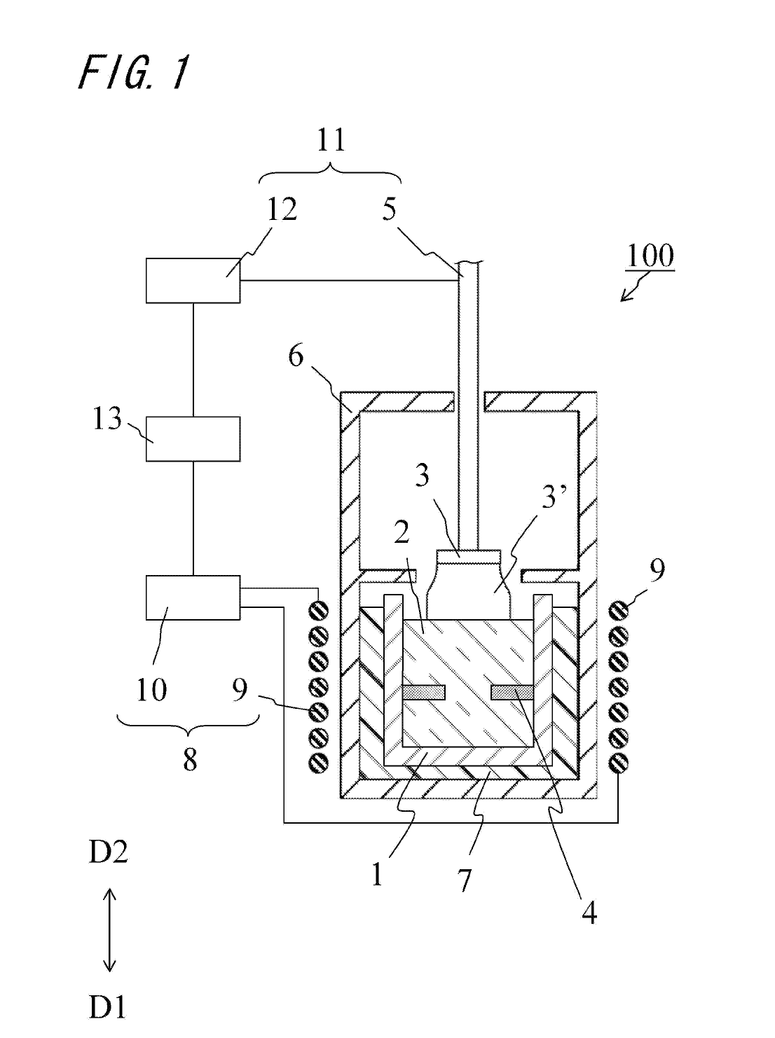

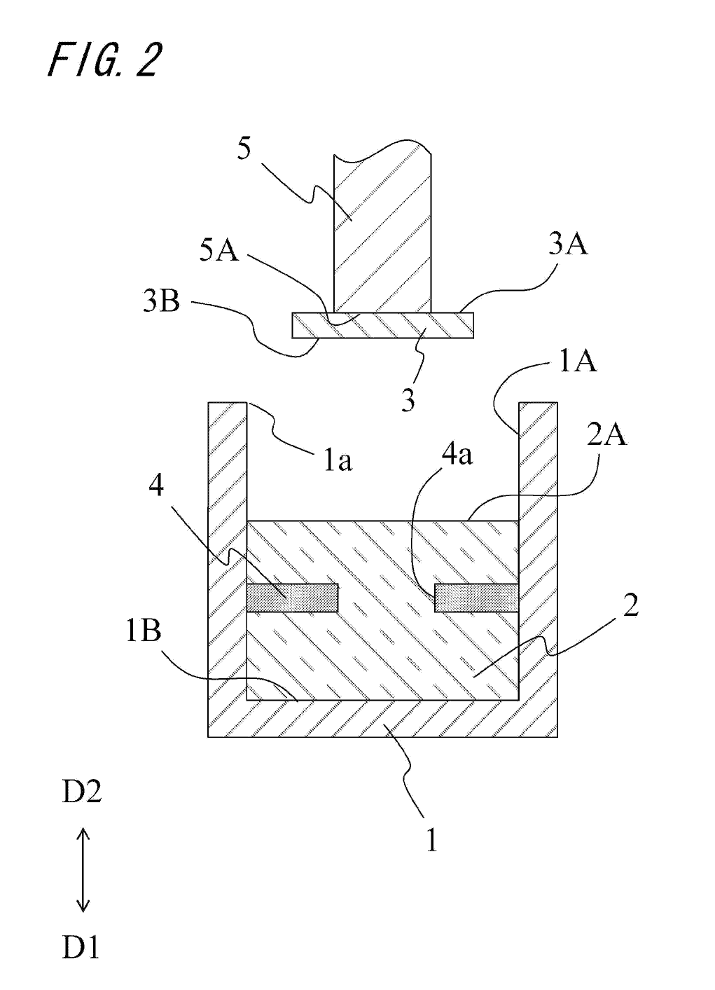

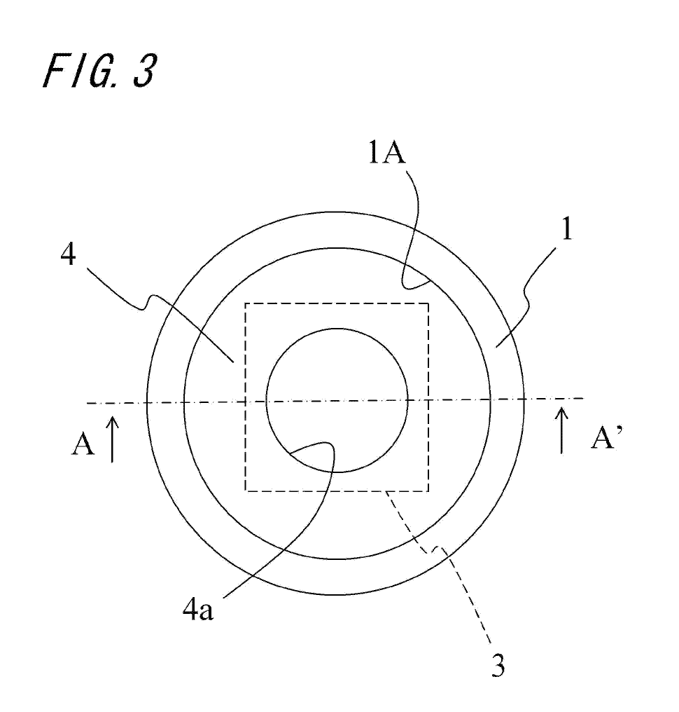

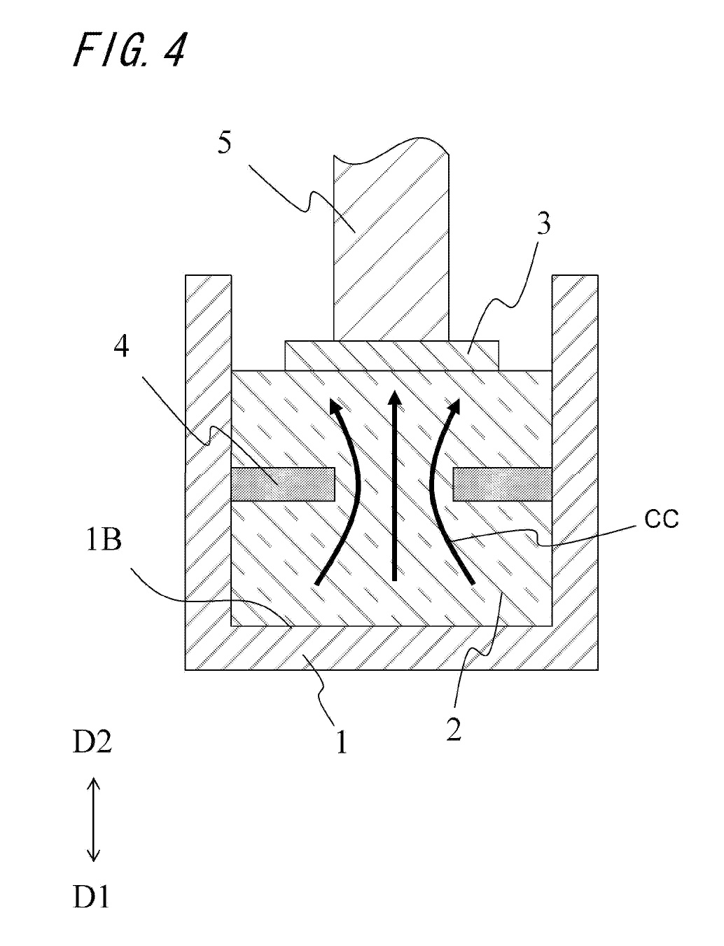

An embodiment of a crucible, a crystal growing apparatus, and a crystal growing method according to the present invention, will be described with reference to FIGS. 1 to 4. FIG. 1 is a schematic cross-sectional view illustrating the crystal growing apparatus according to the embodiment and schematically illustrates the crystal growing apparatus. FIG. 2 is an enlarged view of a part of a longitudinal cross section when the crucible according to the embodiment and a holding member is cut in a vertical direction and illustrates the structure of the crucible and the holding member. FIG. 3 illustrates an upper surface of the crucible according to the embodiment without the solution and illustrates a shape or the like of the crucible and a solution adjustment member. FIG. 4 illustrates an example of a state of convection in a crucible 1 according to the embodiment.

### <Crucible>

The crucible 1 according to the embodiment of the present invention is used in a solution growth method for growing a crystal 3′ of silicon carbide from a solution 2 on a lower surface 3B of a seed crystal 3, by accommodating the solution 2 of silicon containing carbon in the crucible, by allowing the lower surface 3B of the seed crystal 3 to contact with the solution 2 from above, and then, by pulling up the seed crystal 3. The crucible 1 includes a solution adjustment member 4 which includes a through hole 4a overlapped with an inner side of the seed crystal 3 disposed above and which is fixed to an inner wall surface 1A so as to be positioned between a bottom surface 1B of the crucible 1 and a liquid surface 2A of the solution 2 when the solution 2 is accommodated in the crucible 1. The crucible 1 according to the embodiment is installed in a crystal growing apparatus 100 as illustrated in FIG. 1 and is used. The crystal growing apparatus 100 according to the embodiment of the present invention includes the crucible 1 and a holding member 5.

As illustrated in FIGS. 1 and 2, the holding member 5 fixes and holds the seed crystal 3 on a lower end surface 5A via an adhesive or the like. In other words, the holding member 5 is positioned above the seed crystal 3 in a state where the adhesive is present between the holding member 5 and the seed crystal 3. As the adhesive, for example, a carbon adhesive can be used. As appropriately referred to in the following description, in FIG. 1, a downward direction is defined as a direction D1, and an upward direction is defined as a direction D2.

The holding member 5 includes the lower end surface 5A for holding the seed crystal 3. The lower end surface 5A has a polygonal shape, such as a rectangular shape, or a circular shape in plan view. Accordingly, the holding member 5 has a bar shape, such as a polyprism shape or a columnar shape, or a three-dimensional shape, such as a rectangular parallelepiped shape.

The holding member 5 can be made of an appropriate material and made of oxide having a melting point higher than that of the solution 2, such as zirconium oxide or magnesium oxide, or a material which is made of carbon.

When the holding member 5 is made of carbon, it is possible to use, for example, a polycrystal of carbon or a fired body which is made by firing carbon, as the holding member 5. Note that the holding member 5 which is made of carbon is not limited to the holding member 5 which is made of only carbon. The holding member 5 which is made of carbon may include the holding member 5 which contains equal to or greater than 98% carbon by mass %, and may include the holding member 5 which contains a small amount of impurities, such as aluminum, copper, or magnesium, in addition to carbon.

As the seed crystal 3, for example, it is possible to use a monocrystal or a polycrystal of silicon carbide. The thickness of the seed crystal 3 can be set to be equal to or greater than 0.1 mm and equal to or less than 10 mm, for example.

The seed crystal 3 which has, for example, a polygonal outer shape or a circular outer shape in plan view, is used. A maximum width dimension of the seed crystal 3 can be set to be equal to or greater than 5 mm and equal to or less than 20 cm, for example.

As illustrated in FIG. 2, the seed crystal 3 includes an upper surface 3A which is larger than the lower end surface 5A of the holding member 5. In other words, the seed crystal 3, in which the area of the upper surface 3A is larger than the area of the lower end surface 5A of the holding member 5, is used. A part of the upper surface 3A of the seed crystal 3 is fixed to the lower end surface 5A of the holding member 5 via the adhesive. For example, the area of the upper surface 3A of the seed crystal 3 can be set to be equal to or greater than 110% and equal to or less than 400% of the lower end surface 5A.

The seed crystal 3 may be fixed to the lower end surface 5A of the holding member 5 at any position of the upper surface 3A. When the seed crystal 3 is fixed so that a region which includes a center of the seed crystal 3 is overlapped with the lower end surface 5A, the seed crystal 3 can be held with good balance. Accordingly, for example, it is possible to perform crystal growth by stably and horizontally maintaining the lower surface 3B of the seed crystal 3 with respect to the liquid surface 2A of the solution 2.

Next, the crucible 1 will be described. The crucible 1 is made of carbon. The crucible 1 has a function as a container in which a raw material of the monocrystal of silicon carbide to be grown in the crucible 1 is melted. In the embodiment, in the crucible 1, the solution 2 which dissolves carbon therein by using melted silicon as a solvent is retained. In the embodiment, the solution growth method is employed, and the crystal growth is performed by causing a state which is close to thermal equilibrium in the crucible 1.

The solution 2 is located in the crucible 1. The solution 2 dissolves carbon which is an element that forms a crystal of silicon carbide to be grown on the lower surface 3B of the seed crystal 3, in a solution of silicon which is also an element that forms the crystal of silicon carbide. The solubility of an element which becomes a solute increases as the temperature of an element which becomes a solvent increases. Accordingly, by slightly decreasing the temperature of the lower surface 3B of the seed crystal 3 so as to be lower than the temperature of the solution 2, the temperature of the solution 2 which dissolves a large amount of solute in a solvent at a high temperature becomes lower in the vicinity of the seed crystal 3, and the solute is precipitated at a boundary of the thermal equilibrium. By using the precipitation due to the thermal equilibrium, the crystal of silicon carbide can be grown on the lower surface 3B of the seed crystal 3.

The crucible 1 of the embodiment includes the solution adjustment member 4 which is fixed to the inner wall surface 1A. The solution adjustment member 4 of the embodiment is formed in a board shape. A material having a melting point higher than the temperature of the solution 2 is used for the solution adjustment member 4 so as not to melt in the solution 2 as much as possible. For example, the solution adjustment member 4 can use a material which is made of carbon, or an oxide having a melting point higher than the temperature of the solution 2, such as zirconium oxide. When the crucible 1 and the solution adjustment member 4 are made of carbon, for example, the crucible 1 and the solution adjustment member 4 can be fixed by a carbon adhesive, or can be used by being integrally formed.

The thickness of the solution adjustment member 4 may be set to an extent that the member will not be dissolved and lost. The thickness of the solution adjustment member 4 can be set to be equal to or greater than 1 mm and equal to or less than 5 cm, for example. In addition, the thickness of the solution adjustment member 4 can be set to be equal to or greater than 2% and equal to or less than 15% of the distance between the bottom surface 1B and the liquid surface 2A, for example. The thickness of the solution adjustment member 4 may be less than the thickness of the crucible 1, and may be greater than the thickness of the seed crystal 3.

The solution adjustment member 4 is disposed so as to be positioned between the bottom surface 1B and the liquid surface 2A of the solution 2 when the crucible 1 is in use. The solution adjustment member 4 is disposed so that the height from the bottom surface 1B is equal to or greater than 30% and equal to or less than 95% of the height from the bottom surface 1B to the liquid surface 2A, for example. Note that the height when the seed crystal 3 is brought into contact with the solution 2 can be referred to the height of the liquid surface 2A, for example.

As described in FIG. 3, the solution adjustment member 4 includes the through hole 4a which is overlapped with an inner side of the seed crystal 3 disposed above. In other words, when the seed crystal 3 and the solution adjustment member 4 are viewed perspectively (in perspective plan view) from above or below, the through hole 4a is disposed on the inner side of the seed crystal 3. The inner side of the seed crystal 3 indicates inside the outer circumference when the seed crystal 3 is viewed in plan view. As a shape of the through hole 4a in plan view, for example, it is possible to use a polygonal shape, such as a rectangular shape, or a circular shape. The area of the through hole 4a when the through hole 4a is viewed in plan view can be set to be equal to or greater than 60% and equal to or less than 90%, for example, of the area of the lower surface 3B of the seed crystal 3. The area of the through hole 4a can be set to be equal to or greater than 20% and equal to or less than 40%, for example, of the area of an opening portion 1a.

In the crucible 1 of the embodiment, the solution adjustment member 4 includes the through hole 4a which is overlapped with the inner side of the seed crystal 3. The convection which is blocked by the solution adjustment member 4 is concentrated in the through hole 4a, and as illustrated in FIG. 4, convection CC, which flows upwardly through the through hole 4a from the solution 2 located on the lower side of the solution adjustment member 4, is likely to be generated.

Here, carbon supersaturated and precipitated is likely to stay on a lower part in the solution 2, and therefore the concentration distribution of carbon in the solution 2 in the lower part is higher than the concentration in an upper part. Accordingly, by the convection CC, it is possible to allow the solution 2 in the lower part containing a large amount of carbon to easily strike the lower surface 3B of the seed crystal 3. As a result, it is possible to easily grow the crystal of silicon carbide on the lower surface 3B of the seed crystal 3, and to enhance the growing speed of the crystal.

In addition, as illustrated in FIG. 4, since the convection CC containing a large amount of carbon is likely to strike the lower surface 3B of the seed crystal 3, it is possible to suppress, for example, the growth of miscellaneous crystals in the vicinity of a boundary between the inner wall surface 1A and the liquid surface 2A as compared to a case where the carbon is uniformly mixed in the entire solution 2. In other words, with the solution adjustment member 4, it is possible to suppress the growth of the miscellaneous crystals in the solution 2 which is located above the solution adjustment member 4. As a result, since it is possible to make it difficult for the growth of the crystal to be interrupted with the miscellaneous crystals, it is possible to grow the crystal for a longer time on the lower surface 3B of the seed crystal 3.

As illustrated in FIG. 3, when the seed crystal 3 and the solution adjustment member 4 are viewed in perspective plan view, the through hole 4a may be overlapped with the center of the lower surface 3B of the seed crystal 3 disposed above, and may be disposed so as to be overlapped with a half or more of the lower surface 3B. Here, the “center of the lower surface 3B” indicates a center in the drawing when the lower surface 3B is viewed in plan view, and a “half or more of the lower surface 3B” indicates a half or more of the area of the lower surface 3B.

By setting the through hole 4a in this manner, the flow of the convection CC which passes through the through hole 4a and contains a large amount of carbon can be easily directed toward the center of the lower surface 3B. As a result, the convection CC which flows toward the center of the lower surface 3B spreads to the periphery from a center portion of the lower surface 3B, and can uniformly strike the lower surface 3B. Accordingly, it is possible to grow the crystal having a high degree of flatness on the lower surface 3B. As a result, it is possible to suppress generation of bunching or the like on the crystal grown on the lower surface 3B. The shape of the through hole 4a in plan view may be set to be similar to the shape of the lower surface 3B of the seed crystal 3 in plan view.

### (Modification Example 1 of Crucible)

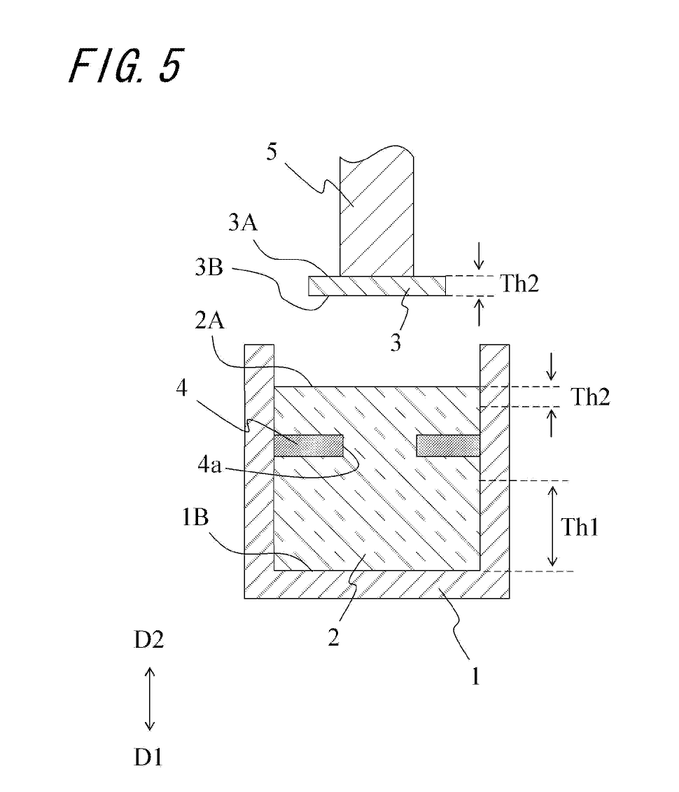

A modification example of the crucible according to the embodiment will be described with reference to FIG. 5. FIG. 5 is a cross-sectional view illustrating a modification example of the crucible 1 according to the embodiment, and illustrates a cross-sectional structure of the crucible 1.

As illustrated in FIG. 5, when the crucible 1 is in use, the solution adjustment member 4 may be positioned higher than an intermediate position Th1 between the bottom surface 1B and the liquid surface 2A of the solution 2, and may be positioned lower from the liquid surface 2A by a thickness Th2 of the seed crystal 3. As the solution adjustment member 4 is positioned at such a height, it is possible to make the distance between the through hole 4a and the seed crystal 3 short, and to make it easy to control striking of the convection CC, which passes through the through hole 4a, on the lower surface 3B.

### (Modification Example 2 of Crucible)

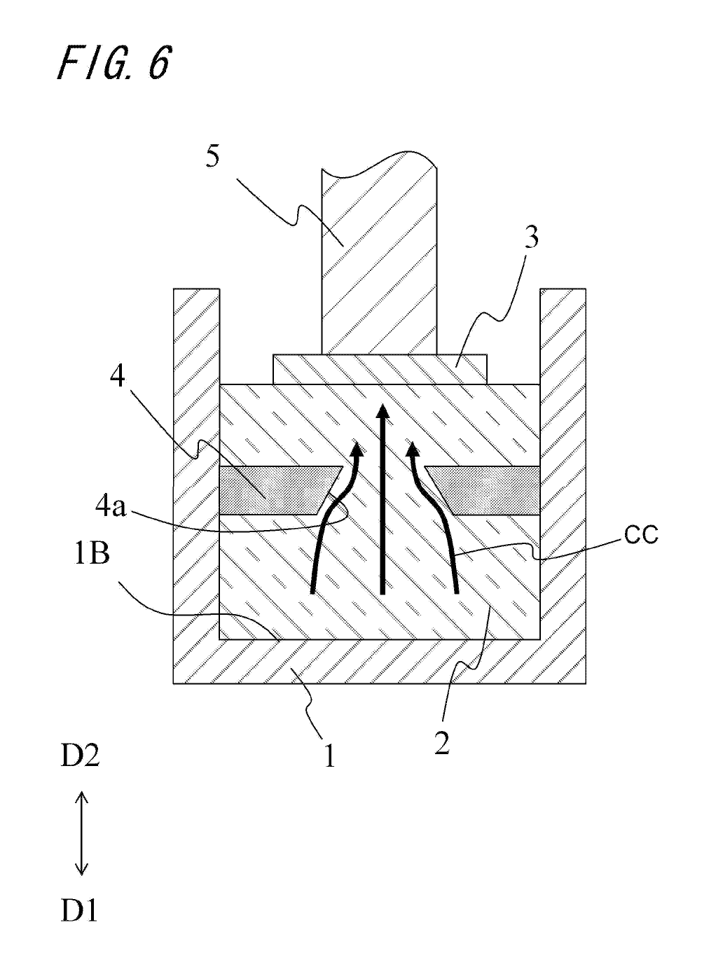

Another modification example of the crucible according to the embodiment will be described with reference to FIG. 6. FIG. 6 is a cross-sectional view illustrating the modification example of the crucible 1 according to the embodiment, and illustrates a cross-sectional structure of the crucible 1.

As illustrated in FIG. 6, a cross-sectional area of the through hole 4a may become smaller toward an upper portion thereof. In this manner, as the cross-sectional area of the through hole 4a becomes smaller as going to an upper direction, it is possible to make the convection CC strike the lower surface 3B in a state where a spread of the flow of the convection CC is suppressed in a horizontal direction of the solution 2 until the convection CC strikes the lower surface 3B. As a result, on the lower surface 3B, it is possible to grow the crystal at a higher speed. Note that the “cross-sectional area” of the through hole 4a indicates a “cross-sectional area which is cut in a horizontal direction” when the through hole 4a is disposed in the vertical direction.

### (Modification Example 3 of Crucible)

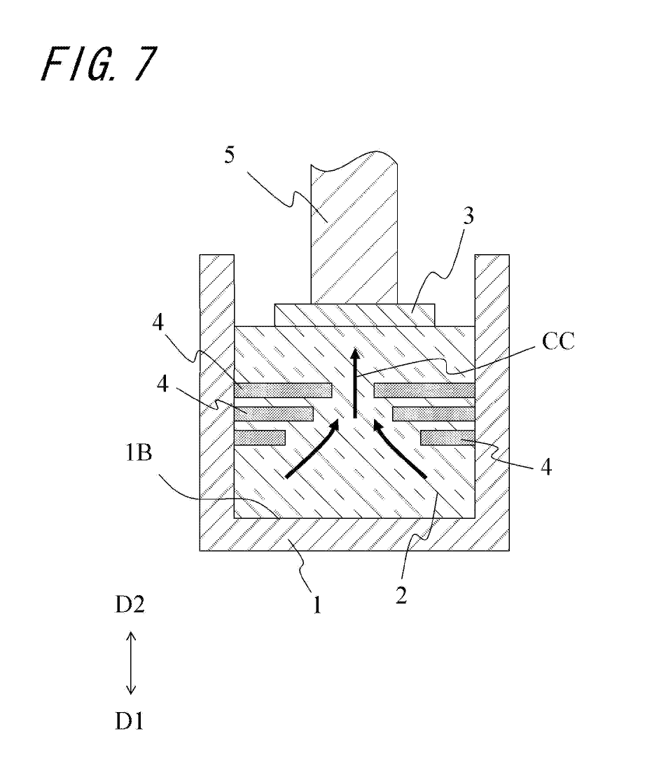

Still another modification example of the crucible according to the embodiment will be described with reference to FIG. 7. FIG. 7 is a cross-sectional view illustrating the modification example of the crucible 1 according to the embodiment, and illustrates a cross-sectional structure of the crucible 1.

As illustrated in FIG. 7, the solution adjustment member 4 may be configured of a plurality of members. The plurality of solution adjustment members 4 are disposed with a certain interval between the members in a vertical direction, and are disposed so that each of the through holes 4a overlaps with another in plan view. The interval between the solution adjustment members 4 may be an interval which makes it difficult to cause the convection between the solution adjustment members 4, and may be set to be equal to or greater than 2 mm and equal to or less than 10 mm, for example. As the plurality of solution adjustment members 4 are disposed in this manner, it is possible to easily control the convection CC which passes through the through holes 4a.

Furthermore, regarding the plurality of the solution adjustment members 4, as illustrated in FIG. 7, in two solution adjustment members 4 which are vertically adjacent to each other among the plurality of the solution adjustment members 4, it is preferable that the through holes 4a vertically overlapped with each other have an opening (a width of the through hole) of the through hole 4a of the solution adjustment member 4 positioned on an upper side which is smaller than an opening of the through hole 4a of the solution adjustment member 4 positioned on a lower side. In this manner, as the solution adjustment members 4 are disposed so that the through hole 4a becomes as small as the through hole 4a positioned above, it is possible to enhance directivity of the convection CC.

### (Modification Example 4 of Crucible)

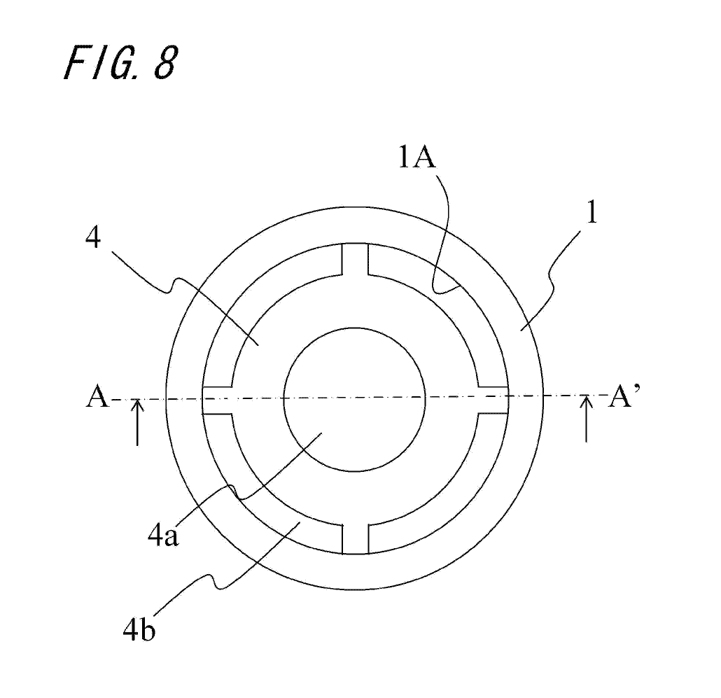

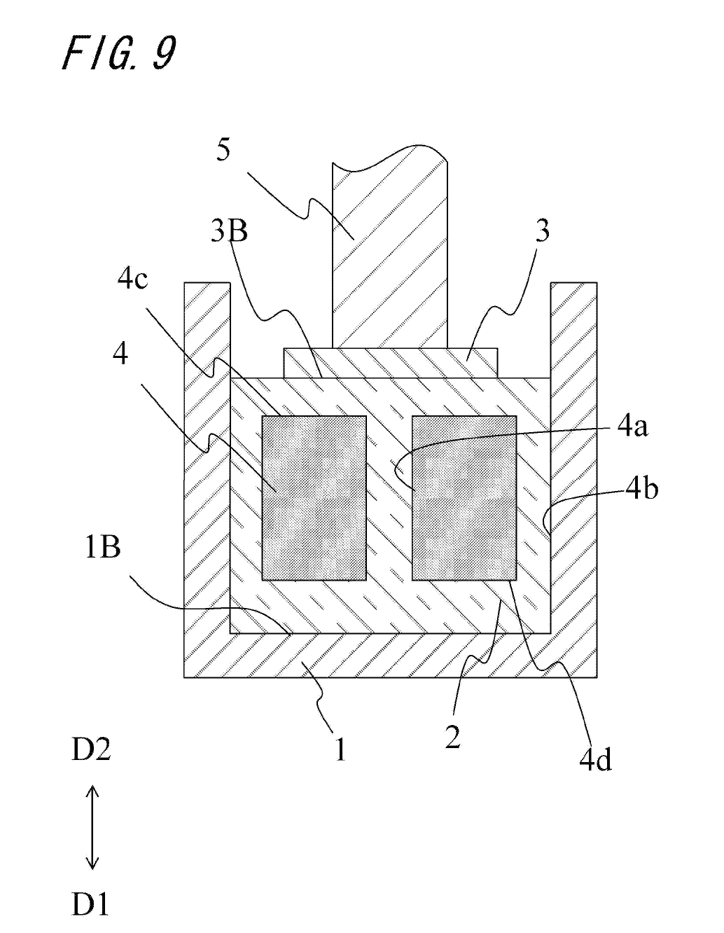

Still another modification example of the crucible according to the embodiment will be described with reference to FIGS. 8 and 9. FIG. 8 is a plan view illustrating the modification example of the crucible 1 according to the embodiment, and illustrates a structure when the crucible 1 is viewed from above without the solution 2. FIG. 9 is a cross-sectional view illustrating the modification example of the crucible 1 according to the embodiment, and illustrates a cross-sectional structure of the crucible 1.

Regarding the solution adjustment member 4, only a part of the solution adjustment member 4 may be fixed to the inner wall surface 1A. In other words, in perspective plan view, a gap 4b may be present between the solution adjustment member 4 and the inner wall surface 1A of the crucible 1. As the gap 4b is present in this manner, the solution 2 can flow from the gap 4b in the direction D1 (downward direction) due to the convection, and the solution 2 can flow from the through hole 4a in the direction D2 (upward direction). As a result, it is possible to increase the amount of the solution 2 which flows from the through hole 4a to the lower surface 3B of the seed crystal 3, and to grow the crystal on the lower surface 3B at a higher speed.

A plurality of gaps 4b may be placed so that each interval between the adjacent gaps 4b is equivalent. In other words, the plurality of gaps 4b may be disposed with the same interval in a circumferential direction. As the plurality of gaps 4b are disposed in this manner, with respect to the solution 2 which flows from the through hole 4a to the gap 4b, it is possible to reduce generation of extreme unevenness of the flow of the solution 2 in a plane direction. As a result, the convection which flows out from the through hole 4a can easily and uniformly strike the lower surface 3B of the seed crystal 3.

The gap 4b may have a shape along the through hole 4a when the crucible 1 and the solution adjustment member 4 are viewed in plan view from above. As the gap 4b has a shape along the through hole 4a in this manner, it is possible to reduce generation of extreme unevenness of the flow of the solution 2 in the plane direction, and to make the convection easily and uniformly strike the lower surface 3B.

The gap 4b may be formed so that the distance from an edge of the through hole 4a to an edge of the gap 4b is constant. As the gap 4b is formed in this manner, it is possible to reduce generation of extreme unevenness of the flow of the solution 2 in the plane direction.

When the solution adjustment member 4 is viewed in plan view from above, the length of the gap 4b along the inner wall surface 1A of the crucible 1 may be longer than a length of the solution adjustment member 4 along the inner wall surface 1A at a portion fixed to the crucible 1. In this manner, as the length of the gap 4b along the inner wall surface 1A is longer than the length of the fixed portion, it is possible to reduce generation of extreme unevenness of the flow of the solution 2 in the plane direction.

When the crucible 1 is viewed in plan view from above, the area of the gap 4b can be set to be equal to or greater than 20% and equal to or less than 50% in total, for example, of the area of the opening portion 1a of the crucible 1. In addition, the area of the gap 4b may be set to be larger than the area of the through hole 4a.

The solution adjustment member 4 may be formed in a columnar shape. The thickness of the solution adjustment member 4 may be set to be equal to 50% or greater than the distance between the bottom surface 1B of the crucible 1 and the liquid surface 2A of the solution 2 when the crucible 1 is used, for example. In this manner, as the thickness of the solution adjustment member 4 is set to be equal to half or greater than the distance between the bottom surface 1B and the liquid surface 2A, it is possible to make the distance between the through hole 4a and the seed crystal 3 short, and to make the flow of the solution 2 which flows out from the through hole 4a easily strike the lower surface 3B.

The thickness of the solution adjustment member 4 may be specifically set to be 60% or more of the distance between the bottom surface 1B and the liquid surface 2A. As the thickness of the solution adjustment member 4 is set in this manner, when the solution 2 convects from the through hole 4a to the gap 4b, and from the gap 4b to the through hole 4a, the overall flow path of the solution 2 can be smaller. As a result, it is possible to reduce generation of a local vortex in the solution 2, for example, to reduce carbon locally stayed in the solution 2, and to easily supply carbon in the solution 2 to the lower surface 3B. In addition, in order not to prevent the growth of the crystal, the maximum thickness of the solution adjustment member 4 is set to be 85% or less of the distance between the bottom surface 1B and the liquid surface 2A, for example. In addition, in this case, in the solution adjustment member 4, a part of a lower surface 3d may be fixed to the bottom surface 1B of the crucible 1.

The solution adjustment member 4 may be positioned so that the distance between an upper surface 4c of the solution adjustment member 4 and the liquid surface 2A of the solution 2 is smaller than the distance between a lower surface 4d of the solution adjustment member 4 and the bottom surface 1B of the crucible 1. In other words, the solution adjustment member 4 may be fixed to the inner wall surface 1A in a state of being close to the liquid surface 2A side. In this manner, as the solution adjustment member 4 is disposed on the liquid surface 2A side in the crucible 1, the flow path of the solution 2 on the lower surface 3B side of the seed crystal 3 can be smaller. As a result, it is possible to make a space right under the lower surface 3B of the seed crystal 3 where irregular convection is generated be small, to reduce generation of the irregular convection, and to reduce the amount of the solution 2 staying right under the lower surface 3B.

### (Modification Example 5 of Crucible)

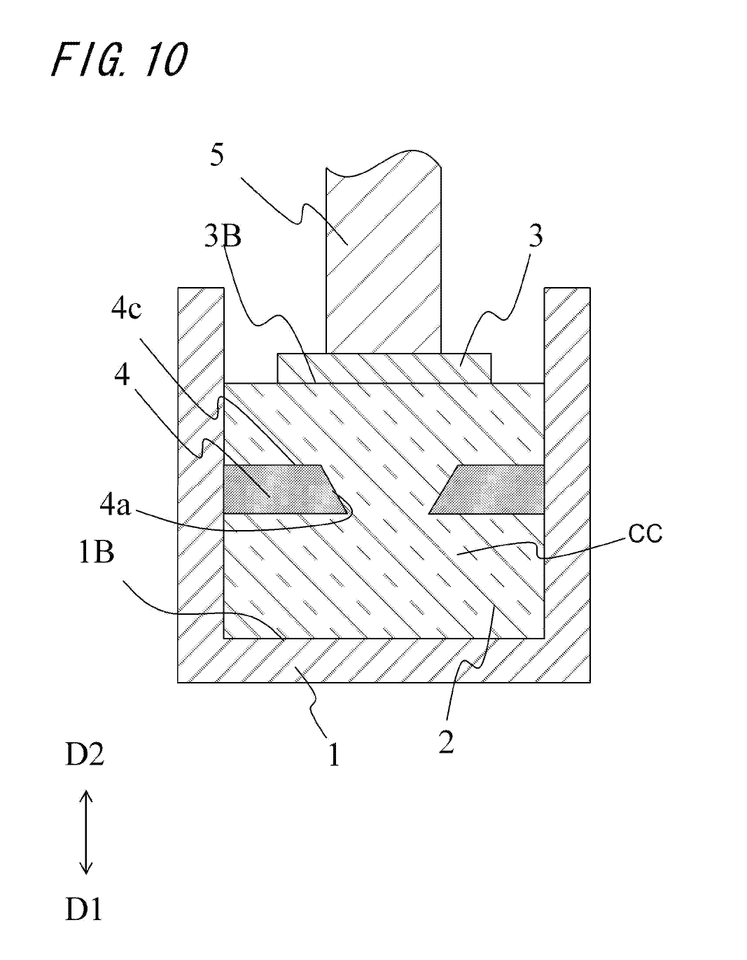

Still another modification example of the crucible according to of the embodiment will be described with reference to FIG. 10. FIG. 10 is a cross-sectional view illustrating the modification example of the crucible 1 according to the embodiment, and illustrates a cross-sectional structure of the crucible 1.

The cross-sectional area of the through hole 4a may be formed to be larger toward an upper portion thereof. As the cross-sectional area of the through hole 4a gradually becomes larger as going to an upper direction, it is possible to reduce a sudden expansion of the flow path of the solution 2 at an opening of the upper surface 4c of the through hole 4a as compared to a case where the cross-sectional area of the through hole 4a does not change. As a result, it is possible to reduce generation of a local vortex in the solution 2 at an edge of the opening of the upper surface 4c.

### (Modification Example 6 of Crucible)

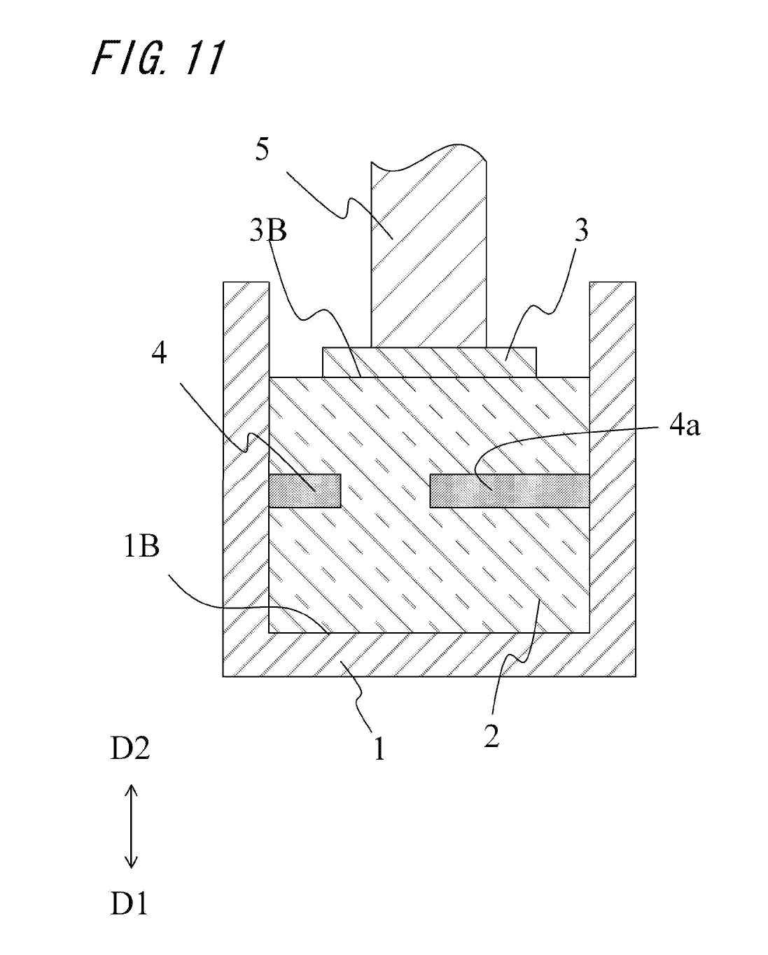

Still another modification example of the crucible according to the embodiment will be described with reference to FIG. 11. FIG. 11 is a cross-sectional view illustrating the modification example of the crucible 1 according to the embodiment, and illustrates a cross-sectional structure of the crucible 1.

The through hole 4a may be positioned such that, when the seed crystal 3 and the solution adjustment member 4a are viewed in perspective plan view, the center of the through hole 4a is not overlapped with the center of the lower surface 3B of the seed crystal 3 which is disposed above. In this manner, as the through hole 4a is disposed to be shifted from the center of the lower surface 3B in plan view, the convection containing a large amount of carbon can easily strike an edge portion of the lower surface 3B, and the crystal can be grown in a step-flow manner from the edge portion of the lower surface 3B of the seed crystal 3 toward the inner side. In addition, in this case, the through hole 4a may be disposed such that, when the seed crystal 3 and the solution adjustment member 4 are viewed in perspective plan view, the center of the through hole 4a is positioned close to an edge of the lower surface 3b rather than a center point of the distance from the center of the lower surface 3B of the seed crystal 3 to the edge of the lower surface 3B.

Note that the present invention is not limited to the above-described embodiments, and can employ various modifications or improvements without departing from the scope of the present invention.

### <Crystal Growing Method>

Next, each element of the crystal growing apparatus 100 according to the embodiment will be described with reference to FIG. 1. The crystal growing apparatus 100 mainly includes the crucible 1 and the holding member 5. The crucible 1 is disposed in a crucible container 6. The crucible container 6 has a function of holding the crucible 1. A heat insulating material 7 is disposed between the crucible container 6 and the crucible 1. The heat insulating material 7 surrounds the periphery of the crucible 1. The heat insulating material 7 controls heat radiation from the crucible 1, and contributes to stabilizing and maintaining the temperature of the crucible 1. In addition, the crucible 1 may be provided being rotatable.

Heat is applied to the crucible 1 by a heating mechanism 8. The heating mechanism 8 of the embodiment employs an induction heating method which heats the crucible 1 by electromagnetic induction, and includes a coil 9 and an AC power supply 10.

The coil 9 is formed of a conductor, and is wound around the periphery of the crucible 1. The AC power supply 10 causes an AC power current to flow to the coil 9, and with a higher AC current flowing, it is possible to shorten time for heating up to a setting temperature in the crucible 1. In the embodiment, the crucible 1 is heated by the induction heating method, but an induction current may be caused to flow in the solution 2 through an electromagnetic field and heat the solution 2 by making the thickness of the crucible 1 thin.

The seed crystal 3 is transported by a transporting mechanism 11 and is placed on the solution 2 of the crucible 1 from the opening portion of the crucible 1 so that a lower surface of the seed crystal 3 contacts with the liquid surface of the solution 2. The transporting mechanism 11 has a function of pulling up the crystal grown on the lower surface of the seed crystal 3 and transporting the crystal from the crucible 1. The transporting mechanism 11 includes the holding member 5 and a power source 12. The seed crystal 3 is transported into the crucible and the crystal grown on the lower surface of the seed crystal 3 is transported out of the crucible via the holding member 5. The seed crystal 3 is attached to the lower end surface of the holding member 5, and the holding member 5 controls movement in the vertical direction (directions D1 and D2) through the power source 12. In other words, the holding member 5 is capable of holding the seed crystal 3 on the lower end surface thereof, and inserting or pulling up the seed crystal 3 from the opening portion of the crucible 1. The holding member 5 may be provided being rotatable.

In the crystal growing apparatus 100, the AC power supply 10 of the heating mechanism 8 and the power source 12 of the transporting mechanism 11 are connected to a control portion 13 and are controlled. In other words, in the crystal growing apparatus 100, operations of heating the solution 2, controlling the temperature of the solution 2, and transporting in and out of the seed crystal 3 are controlled by the control portion 13 in association with each other. The control portion 13 includes a central processing unit and a storage apparatus such as a memory, and is configured by, for example, a known computer.

The above-described holding member 5 is attached to the transporting mechanism 11 of the crystal growing apparatus 100 according to the embodiment. It is possible to allow the lower surface of the seed crystal 3 fixed to the lower end surface of the holding member 5 to contact with the solution 2, and to grow the crystal on the lower surface of the seed crystal 3.

With respect to the solution 2 of silicon containing carbon, the crystal growing apparatus 100 including the above-described crucible 1 in this manner can cause the convection of the solution 2 containing a large amount of carbon to easily strike the lower surface of the seed crystal 3, and can grow the crystal of silicon carbide on the lower surface of the seed crystal 3 at a high speed.

### <Crystal Growing Method>

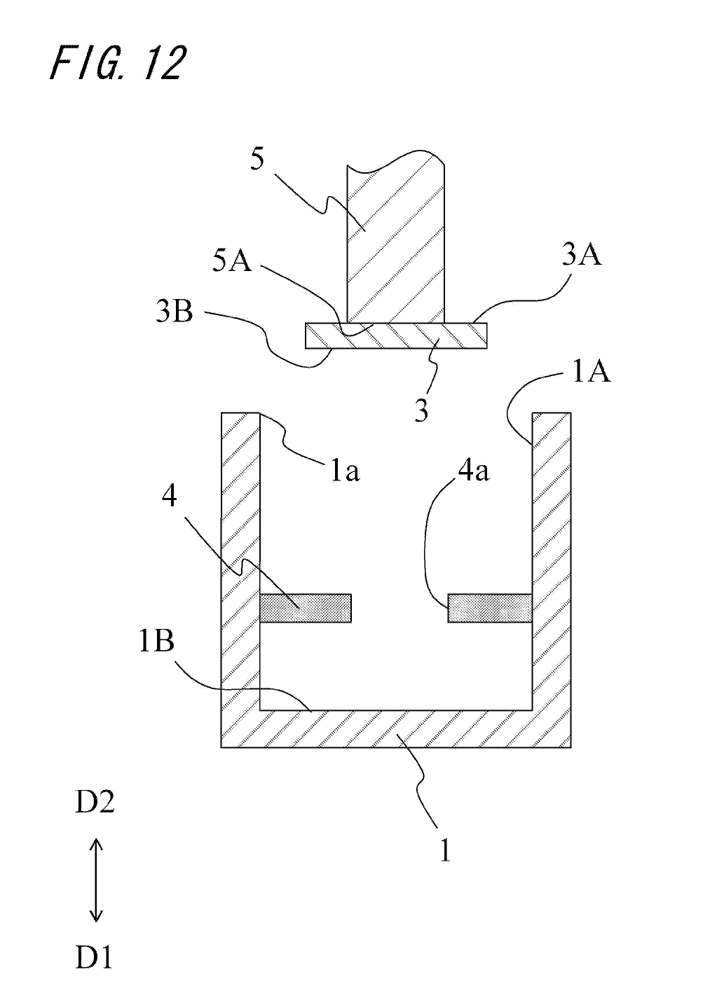

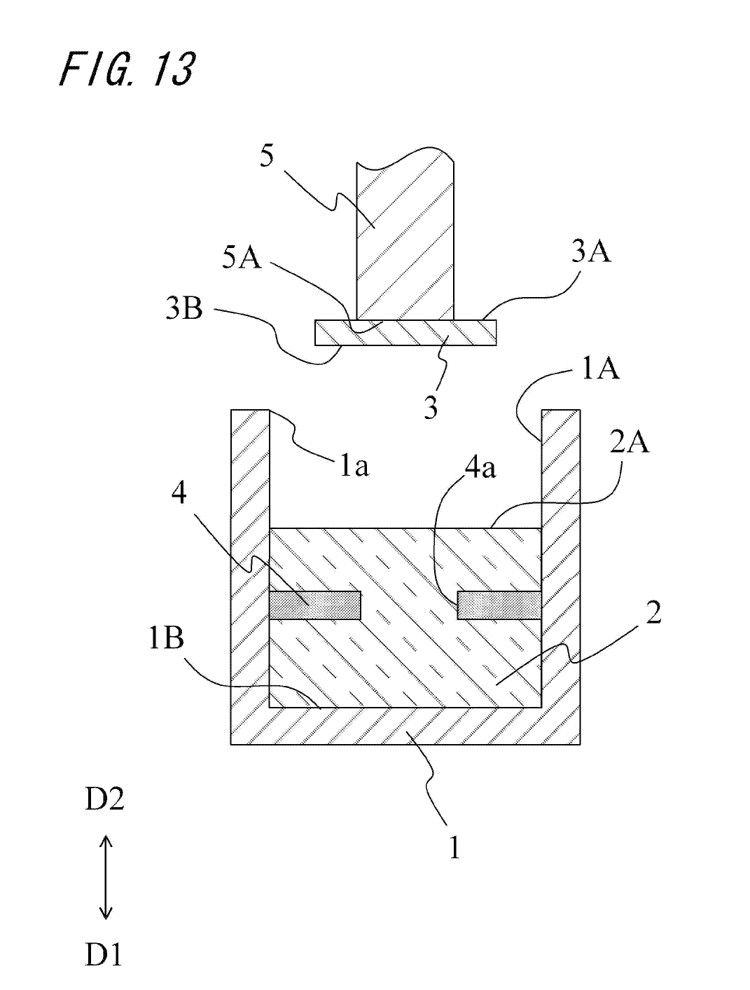

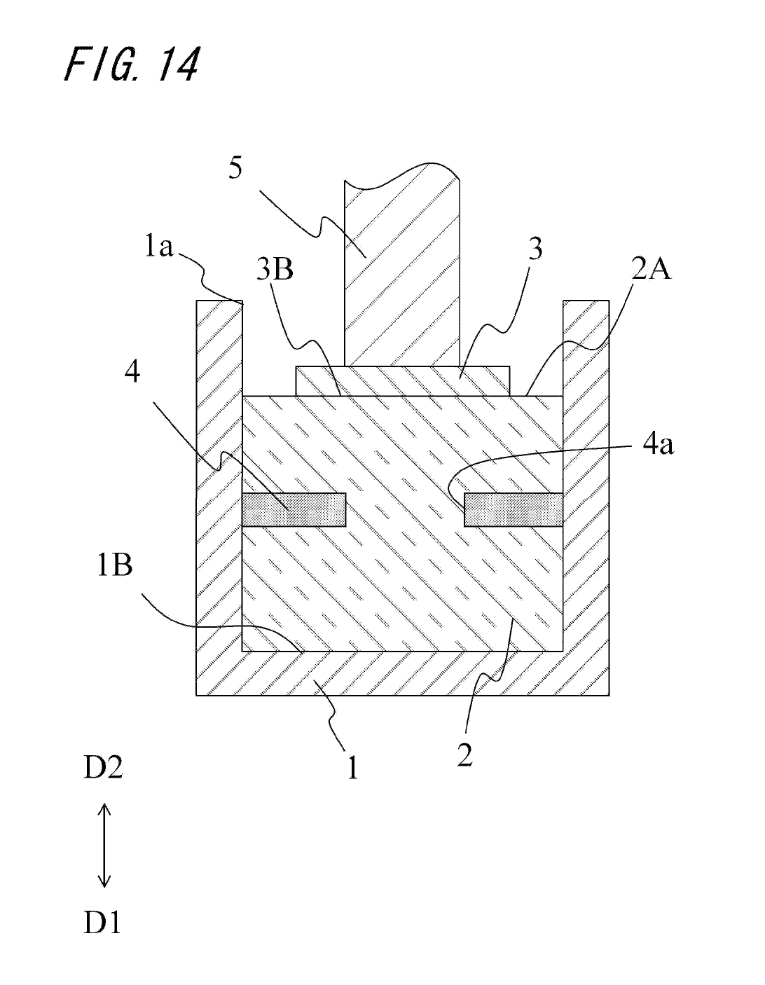

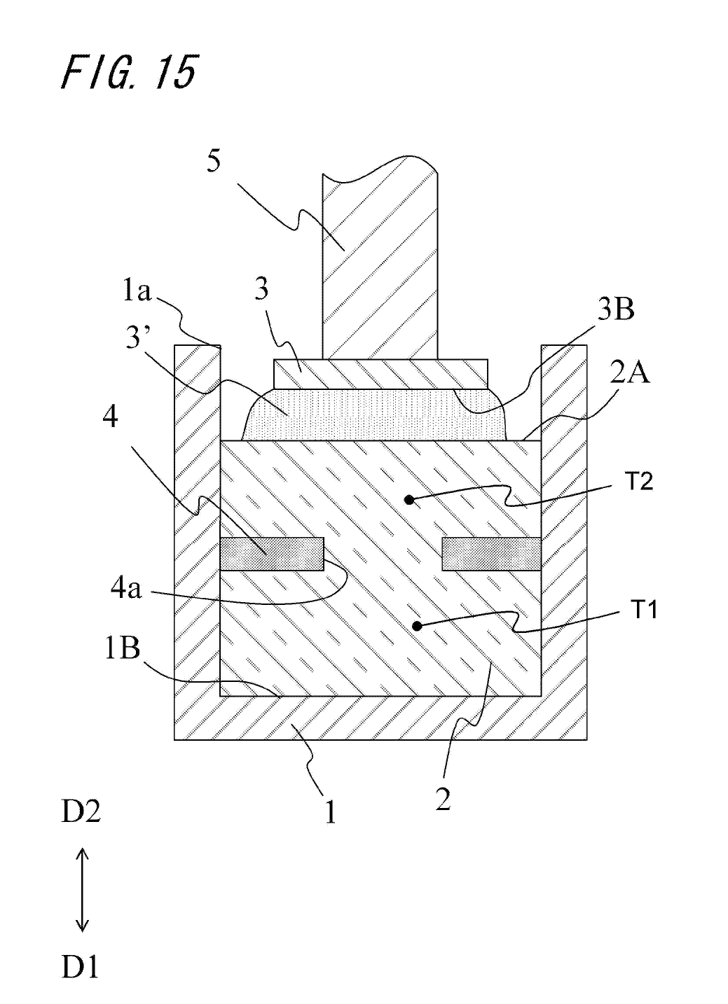

Next, the crystal growing method according to the embodiment of the present invention will be described. The crystal growing method according to the embodiment of the present invention includes a preparation process, a solution accommodation process, a contact process, and a crystal growing process. FIG. 12 is a diagram illustrating an example of the preparation process of the crystal growing method, and illustrates the crucible 1, the seed crystal 3, and the holding member 5. FIG. 13 is a diagram illustrating an example of the solution accommodation process of the crystal growing method, and illustrates a state where the solution 2 is accommodated in the crucible 1. FIG. 14 is a diagram illustrating an example of the contact process of the crystal growing method, and illustrates a state where the lower surface 3B of the seed crystal 3 is brought into contact with the liquid surface 2A of the solution 2. FIG. 15 is a diagram illustrating an example of a crystal growing process of the crystal growing method, and illustrates a state where a crystal 3′ is grown on the lower surface 3B of the seed crystal 3.

### (Preparation Process)

As illustrated in FIG. 12, in the preparation process, the above-described crucible 1, the holding member 5 which is capable of inserting and pulling up the seed crystal 3 through the opening portion 1a of the crucible 1 into the inside thereof, and the seed crystal 3 which is made of silicon carbide and whose upper surface 3A is held by the holding member 5 are prepared.

### (Solution Accommodation Process)

Next, as illustrated in FIG. 13, the solution 2 is accommodated in the crucible 1 such that the liquid surface 2A is positioned above the solution adjustment member 4. As a method for accommodating the solution 2 in the crucible 1, particles which contains silicon as a main component is placed in the crucible 1, the crucible 1 or the particles is heated by the heating mechanism 8, and the particles is dissolved. At this time, the carbon particles is mixed, and/or carbon is melted and flows out of a part of the crucible 1. According to this, the solution 2 of silicon containing carbon is accommodated in the crucible 1.

### (Contact Process)

Subsequently, as illustrated in FIG. 14, the seed crystal 3 is placed in the crucible 1 from the opening portion 1a of the crucible 1 by the holding member 5, and the lower surface 3B of the seed crystal 3 is brought into contact with the liquid surface 2A of the solution 2. At this time, the entire seed crystal 3 may be dipped into the solution 2 once, and may be meltbacked.

### (Crystal Growing Process)

Subsequently, as illustrated in FIG. 15, in a state where the seed crystal 3 is disposed such that the lower surface 3B thereof is overlapped with the through hole 4a of the solution adjustment member 4 when the seed crystal 3 and the solution adjustment member 4 are viewed in perspective plan view, the crystal of silicon carbide is grown on the lower surface 3B. Then, as the holding member 5 is gradually pulled up upwardly, it is possible to continuously grow the crystal 3′ on the lower surface 3B in the direction D1 (downward direction). In the above-described contact process, the seed crystal 3 may be disposed so that the lower surface 3b is brought into contact with the solution 2 and at the same time is overlapped with the through hole 4a of the solution adjustment member 4, or may be disposed so that the lower surface 3b is overlapped with the through hole 4a after allowing the lower surface 3b to contact with the solution 2. In the case where the crystal 3′ is grown on the lower surface 3B, the lower end surface of the crystal 3′ corresponds to the lower surface 3B with the growth of the crystal 3′.

In the crystal growing method according to the embodiment, since the crystal 3′ is grown on the lower surface 3B of the seed crystal 3 by using the above-described crucible 1, the convection of the solution 2 containing a large amount of carbon can easily strike the lower surface 3B of the seed crystal 3, and the growing speed of the crystal 3′ on the lower surface 3B can increase. As a result, it is possible to improve productivity of the crystal 3′ grown on the lower surface 3B. The crystal 3′ may be grown while rotating the crucible 1 or the holding member 5.

### (Modification Example of Crystal Growing Method)

In the crystal growing process, as illustrated in FIG. 15, a temperature T1 of the solution 2 located below the solution adjustment member 4 may be higher than a temperature T2 of the solution 2 located above the solution adjustment member 4. Here, when a plurality of solution adjustment members 4 exist in the vertical direction, it is possible to use, as the temperature T1, the temperature of the solution 2 located below the solution adjustment member 4 which is positioned at the lowermost end, and to use, as the temperature T2, the temperature of the solution 2 located above the solution adjustment member 4 which is positioned at the uppermost end.

By making the temperature T1 higher than the temperature T2, it is possible to have a temperature difference in the solution 2. When the temperature difference exists in the solution 2 in this manner, it is possible to cause the convection to be easily generated from the high temperature T2 side to the low temperature T1 side. As a result, it is possible to increase the convection toward the lower surface 3B of the seed crystal 3, and to enhance the growing speed of the crystal 3′ which is grown on the lower surface 3B.

1. A crucible, accommodating a solution of silicon containing carbon thereinside, for a solution growth method for growing a crystal of silicon carbide on a lower surface of a seed crystal from the solution, by allowing a lower surface of the seed crystal to contact with the solution from above and then pulling the seed crystal upward, the crucible comprising:
a solution adjustment member that comprises a through hole overlapped with an inner side of the seed crystal disposed above and that is fixed to an inner wall surface of the crucible so as to be positioned between a bottom surface of the crucible and a liquid surface of the solution when the crucible is used,
wherein the crucible is made of carbon.

2. The crucible according to claim 1, wherein
the through hole is overlapped with a center of the lower surface of the seed crystal disposed above and is overlapped with 50% or more of the lower surface of the seed crystal.

3. The crucible according to claim 1, wherein
a cross-sectional area of the through hole becomes smaller as going to an upper direction.

4. The crucible according to claim 1,
comprising a plurality of solution adjustment members, each of solution adjustment members is the solution adjustment member, and
wherein the plurality of the solution adjustment members are disposed in a vertical direction with a certain interval and with respective through holes overlapped with each other.

5. The crucible according to claim 4, wherein
in the through holes which are vertically overlapped in the two solution adjustment members which are vertically adjacent to each other among the plurality of the solution adjustment members, an opening on the upper side of the through hole positioned on the upper side is smaller than an opening on the upper side of the through hole positioned on the lower side.

6. A crystal growing apparatus, comprising:
the crucible according to claim 1; and
a holding member that holds a seed crystal and is capable of inserting and pulling up the seed crystal from an opening portion of the crucible.

7. A crystal growing method, comprising:
preparing the crucible according to claim 1, a holding member that holds a seed crystal and is capable of inserting and pulling up the seed crystal from an opening portion of the crucible, and the seed crystal which is made of silicon carbide and whose upper surface is held by the holding member;
accommodating inside the crucible a solution of silicon containing carbon so that the liquid surface is positioned above the solution adjustment member;
allowing a lower surface of the seed crystal to contact with the solution by inserting the seed crystal from the opening portion of the crucible by the holding member; and
growing the crystal of silicon carbide on a lower surface of the seed crystal by pulling up the seed crystal by the holding member in a state where the lower surface of the seed crystal is disposed to be overlapped with the through hole of the solution adjustment member.

8. The crystal growing method according to claim 7, wherein
in the growing of the crystal of silicon carbide, a temperature of the solution positioned below the solution adjustment member is higher than a temperature of the solution positioned above the solution adjustment member.

9. The crucible according to claim 2, wherein
a cross-sectional area of the through hole becomes smaller as going to an upper direction.

10. The crucible according to claim 2,
comprising a plurality of solution adjustment members, each of solution adjustment members is the solution adjustment member, and
wherein the plurality of the solution adjustment members are disposed in a vertical direction with a certain interval and with respective through holes overlapped with each other.

11. The crucible according to claim 3,
comprising a plurality of solution adjustment members, each of solution adjustment members is the solution adjustment member, and
wherein the plurality of the solution adjustment members are disposed in a vertical direction with a certain interval and with respective through holes overlapped with each other.

12. The crucible according to claim 9,
comprising a plurality of solution adjustment members, each of solution adjustment members is the solution adjustment member, and
wherein the plurality of the solution adjustment members are disposed in a vertical direction with a certain interval and with respective through holes overlapped with each other.
